(19) United States
(12) Patent Application Publication
(10) Pub. No.: US 2013/0248842 A1
(43) Pub. Date: Sep. 26, 2013

(54) ORGANIC ELECTRONIC DEVICE WITH COMPOSITE ELECTRODE

(71) Applicants: Weiying Gao, Landenberg, PA (US); Ying Wang, Wilmington, DE (US)

(72) Inventors: Weiying Gao, Landenberg, PA (US); Ying Wang, Wilmington, DE (US)

(73) Assignee: E I DU PONT DE NEMOURS AND COMPANY, Wilmington, DE (US)

(21) Appl. No.: 13/989,177

(22) PCT Filed: Nov. 30, 2011
(86) PCT No.: PCT/US11/62687

§ 371 Date: May 23, 2013

Related U.S. Application Data
(60) Provisional application No. 61/418,531, filed on Dec. 1, 2010.

(51) Int. Cl. H05K 1/09; H01L 51/44; H05K 1/02; H01L 51/52

(52) U.S. Cl. CPC H05K 1/09; H01L 51/5206; H01L 51/441; H05K 1/02
USPC 257/40; 174/250; 174/257

(57) ABSTRACT

There is provided a composite electrode including either a single layer or a bilayer. The single layer electrode includes an alloy of a first metal having an electrical conductivity greater than 10⁵ Scm⁻¹ and a real refractive index less than 2.1 in the range of 380 to 780 nm. The bilayer electrode includes:
(a) layer M1 having a first thickness and including the first metal; and
(b) layer M2 having a second thickness and including a second metal, where the second metal has an electrical conductivity less than 10⁵ Scm⁻¹.
   In the bilayer electrode, layer M1 is in physical contact with layer M2, and the first thickness is greater than the second thickness.

### RELATED APPLICATION DATA

This application claims priority under 35 U.S.C. §119(e) from U.S. Provisional Application No. 61/418,531 filed on Dec. 1, 2010, which is incorporated by reference herein in its entirety.

### BACKGROUND INFORMATION

1. Field of the Disclosure

This disclosure relates in general to organic electronic devices and particularly to devices including a composite electrode.

2. Description of the Related Art

In organic electronic devices, such as organic light emitting diodes (“OLED”), that make up OLED displays, the organic active layer is sandwiched between two electrical contact layers. In an OLED, at least one of the electrical contact layers is light-transmitting, and the organic active layer emits light through the light-transmitting electrical contact layer upon application of a voltage across the electrical contact layers.

It is well known to use organic electroluminescent compounds as the active component in light-emitting diodes. Simple organic molecules, conjugated polymers, and organometallic complexes have been used. Devices frequently include one or more charge transport layers, which are positioned between a photoactive (e.g., light-emitting) layer and an electrical contact layer. A device can contain two or more contact layers. A hole transport layer can be positioned between the photoactive layer and the hole-injecting contact layer. The hole-injecting contact layer may also be called the anode. An electron transport layer can be positioned between the photoactive layer and the electron-injecting contact layer. The electron-injecting contact layer may also be called the cathode. Charge transport materials can also be used as hosts in combination with the photoactive materials.

There is a continuing need for devices with improved properties.

### SUMMARY

There is provided a composite electrode comprising one of (a) a single layer A1 and (b) a bilayer, wherein the single layer A1 comprises an alloy of a first metal having an electrical conductivity greater than 10⁵ Scm⁻¹ and a real refractive index less than 2.1 in the range of 380 to 780 nm; and the bilayer comprises:

(a) layer M1 having a first thickness and comprising the first metal; and

(b) layer M2 having a second thickness and comprising a second metal or an alloy of the second metal, where the second metal has an electrical conductivity less than 10⁵ Scm⁻¹;

wherein layer M1 is in physical contact with layer M2 and the first thickness is greater than the second thickness.

There is further provided an organic electronic device comprising an anode and a cathode, with a photoactive layer therebetween, wherein the anode is the abovedescribed composite electrode.

The foregoing general description and the following detailed description are exemplary and explanatory only and are not restrictive of the invention, as defined in the appended claims.

### BRIEF DESCRIPTION OF THE DRAWINGS

Embodiments are illustrated in the accompanying figures to improve understanding of concepts as presented herein.

FIG. 1 includes an illustration of one example of an organic electronic device.

FIG. 2 includes an illustration of an organic electronic device with a composite anode.

FIG. 3 includes another illustration of an organic electronic device with a composite anode.

FIG. 4 includes another illustration of an organic electronic device with a composite anode.

FIG. 5 includes another illustration of an organic electronic device with a composite anode.

FIG. 6 includes another illustration of an organic electronic device with a composite anode.

FIG. 7 includes another illustration of an organic electronic device with a composite anode.

FIG. 8 includes another illustration of an organic electronic device with a composite anode.

FIG. 9 includes another illustration of an organic electronic device with a composite anode.

FIG. 10 includes another illustration of an organic electronic device with a composite anode.

FIG. 11 includes another illustration of an organic electronic device with a composite anode.

FIG. 12 includes another illustration of an organic electronic device with a composite anode.

FIG. 13 includes another illustration of an organic electronic device with a composite anode.

FIG. 14 includes another illustration of an organic electronic device with a composite anode.

Skilled artisans appreciate that objects in the figures are illustrated for simplicity and clarity and have not necessarily been drawn to scale. For example, the dimensions of some of the objects in the figures may be exaggerated relative to other objects to help to improve understanding of embodiments.

### DETAILED DESCRIPTION

Many aspects and embodiments have been described above and are merely exemplary and not limiting. After reading this specification, skilled artisans appreciate that other aspects and embodiments are possible without departing from the scope of the invention.

Other features and benefits of any one or more of the embodiments will be apparent from the following detailed description, and from the claims. The detailed description first addresses Definitions and Clarification of Terms, followed by the Composite Electrode, the Electronic Device, and Examples.

### 1. Definitions and Clarification of Terms

Before addressing details of embodiments described below, some terms are defined or clarified.

The term “blue” is intended to mean radiation that has an emission maximum at a wavelength in a range of approximately 400-500 nm.

The term “charge transport,” when referring to a layer, material, member, or structure is intended to mean such layer, material, member, or structure facilitates migration of such charge through the thickness of such layer, material, member, or structure with relative efficiency and small loss of charge. Hole transport materials facilitate positive charge; electron transport material facilitate negative charge. Although light-emitting materials may also have some charge transport properties, the term “charge transport layer, material, member, or structure” is not intended to include a layer, material, member, or structure whose primary function is light emission or light absorption.

The term “dopant” is intended to mean a material, within a layer including a host material, that changes the electronic characteristic(s) or the targeted wavelength(s) of radiation emission, reception, or filtering of the layer compared to the electronic characteristic(s) or the wavelength(s) of radiation emission, reception, or filtering of the layer in the absence of such material. A dopant of a given color refers to a dopant which emits light of that color.

The term “green” is intended to mean radiation that has an emission maximum at a wavelength in a range of approximately 500-580 nm.

The term “hole injection” when referring to a layer, material, member, or structure, is intended to mean such layer, material, member, or structure facilitates injection and migration of positive charges through the thickness of such layer, material, member, or structure with relative efficiency and small loss of charge.

The term “host material” is intended to mean a material, usually in the form of a layer, to which a dopant may or may not be added. The host material may or may not have electronic characteristic(s) or the ability to emit, receive, or filter radiation. When a dopant is present in a host material, the host material does not significantly change the emission wavelength of the dopant material.

The term “photoactive” is intended to mean a material that emits light when activated by an applied voltage (such as in a light emitting diode or chemical cell) or responds to radiant energy and generates a signal with or without an applied bias voltage (such as in a photodetector or a photovoltaic cell).

The term “red” is intended to mean radiation that has an emission maximum at a wavelength in a range of approximately 580-700 nm.

The term “refractive index” or “index of refraction” of a substance is a measure of the speed of light in that substance. It is expressed as a ratio of the speed of light in vacuum relative to that in the considered medium. In general, a refractive index is a complex number with both a real and imaginary part, where the imaginary part is sometimes called the extinction coefficient k. As used herein, the “real refractive index” refers to the real part of the complex number. The refractive index depends strongly on the wavelength of light.

The term “small molecule,” when referring to a compound, is intended to mean a compound which does not have repeating monomeric units. In one embodiment, a small molecule has a molecular weight no greater than approximately 2000 g/mol.

As used herein, the terms “comprises,” “comprising,” “includes,” “including,” “has,” “having” or any other variation thereof, are intended to cover a non-exclusive inclusion. For example, a process, method, article, or apparatus that comprises a list of elements is not necessarily limited to only those elements but may include other elements not expressly listed or inherent to such process, method, article, or apparatus. Further, unless expressly stated to the contrary, “or” refers to an inclusive or and not to an exclusive or. For example, a condition A or B is satisfied by any one of the following: A is true (or present) and B is false (or not present), A is false (or not present) and B is true (or present), and both A and B are true (or present).

Also, use of “a” or “an” are employed to describe elements and components described herein. This is done merely for convenience and to give a general sense of the scope of the invention. This description should be read to include one or at least one and the singular also includes the plural unless it is obvious that it is meant otherwise.

Group numbers corresponding to columns within the Periodic Table of the elements use the “New Notation” convention as seen in the CRC Handbook of Chemistry and Physics, 81^{st} Edition (2000-2001).

Unless otherwise defined, all technical and scientific terms used herein have the same meaning as commonly understood by one of ordinary skill in the art to which this invention belongs. Although methods and materials similar or equivalent to those described herein can be used in the practice or testing of embodiments of the present invention, suitable methods and materials are described below. All publications, patent applications, patents, and other references mentioned herein are incorporated by reference in their entirety, unless a particular passage is cited in case of conflict, the present specification, including definitions, will control. In addition, the materials, methods, and examples are illustrative only and not intended to be limiting.

To the extent not described herein, many details regarding specific materials, processing acts, and circuits are conventional and may be found in textbooks and other sources within the organic light-emitting diode display, photodetector, photovoltaic, and semiconductive member arts.

### 2. Composite Electrode

The composite electrode comprises one of (a) a single layer A1 and (b) a bilayer, wherein the single layer A1 comprises an alloy of a metal having an electrical conductivity greater than 10⁵ Scm⁻¹ and a real refractive index less than 2.1 in the range of 380 to 780 nm; and the bilayer comprises:

(a) layer M1 having a first thickness and comprising the first metal; and

(b) layer M2 having a second thickness and comprising a second metal or an alloy of the second metal, where the second metal has an electrical conductivity less than 10⁵ Scm⁻¹;

wherein layer M1 is in physical contact with layer M2 and the first thickness is greater than the second thickness.

a. Single Layer

In some embodiments, the composite electrode comprises a single layer A1. The single layer A1 comprises an alloy of a first metal, where the first metal has an electrical conductivity greater than 10⁵ Scm⁻¹ and a real refractive index less than 2.1 in the range of 380 to 780 nm. In some embodiments, the first metal has an electrical conductivity greater than 2×10⁵ Scm⁻¹.

In some embodiments, layer A1 consists essentially of an alloy of the first metal.

In some embodiments, the alloy is at least 60% by weight of the first metal; in some embodiments, at least 70% by weight; in some embodiments, at least 80% by weight; in some embodiments, at least 90% by weight; in some embodiments, at least 95% by weight.

In some embodiments, the first metal is copper, silver or gold.

In some embodiments, the first metal is copper, which has an electrical conductivity of 6.0×10⁵ Scm⁻¹ and a real refractive index of 0.25 to 1.2 in the range of 380 to 780 nm.

In some embodiments, the first metal is silver, which has an electrical conductivity of 6.3×10⁵ Scm⁻¹ and a real refractive index of 0.2 to 0.15 in the range of 380 to 780 nm.

In some embodiments, the first metal is gold, which has an electrical conductivity of 4.5×10⁵ Scm⁻¹ and a real refractive index in the range of 1.7 to 0.2 in the range of 380 to 780 nm.

In some embodiments, the alloy metal is silver, gold, copper, nickel, palladium, germanium or titanium.

In some embodiments, the composite electrode comprises silver/gold, silver/gold/copper, gold/nickel, gold/palladium, silver/germanium, silver/copper, silver/palladium, silver/nickel, or silver/titanium. In some embodiments, the composite electrode consists essentially of silver/gold, silver/gold/copper, gold/nickel, gold/palladium, silver/germanium, silver/copper, silver/palladium, silver/nickel, or silver/titanium.

In some embodiments, the single layer A1 has a thickness in the range of 5-50 nm; in some embodiments, 10-30 nm.

Layer A1 can be formed by any conventional deposition technique for forming layers, including vapor deposition, liquid deposition (continuous and discontinuous techniques), and thermal transfer. In some embodiments, layer A1 is formed by a vapor deposition process. Such processes are well known in the art.

b. Bilayer Electrode

In some embodiments, the composite electrode comprises a bilayer. The bilayer comprises

(a) layer M1 having a first thickness and comprising the first metal as described above; and

(b) layer M2 having a second thickness and comprising a second metal or an alloy of the second metal, where the second metal has an electrical conductivity less than 10⁵ Scm⁻¹.

Layer M1 is in physical contact with layer M2 and the first thickness is greater than the second thickness.

In some embodiments, layer M1 consists essentially of the first metal.

In some embodiments, layer M2 consists essentially of the second metal or an alloy of the second metal. In some embodiments, layer M2 consists essentially of the second metal.

In some embodiments, the ratio of M1 thickness to M2 thickness is at least 5:1; in some embodiments, at least 10:1.

In some embodiments, the first metal has a thermal conductivity that is greater than the thermal conductivity of the second metal.

In some embodiments, the first metal is copper, silver, gold, or an alloy thereof.

In some embodiments, the first metal is copper, which has an electrical conductivity of 6.0×10⁵ Scm⁻¹, a real refractive index of 1.2 to 0.25 in the range of 380 to 780 nm, and a thermal conductivity of 4.01 watts/cm° C.

In some embodiments, the first metal is silver, which has an electrical conductivity of 6.3×10⁵ Scm⁻¹, a real refractive index of 0.2 to 0.15 in the range of 380 to 780 nm, and a thermal conductivity of 4.29 watts/cm° C.

In some embodiments, the first metal is gold, which has an electrical conductivity of 4.5×10⁵ Scm⁻¹, a real refractive index in the range of 1.7 to 0.2 in the range of 380 to 780 nm, and a thermal conductivity of 3.17 watts/cm° C.

In some embodiments, layer M1 consists essentially of copper, silver, or gold.

In some embodiments, layer M1 has a thickness in the range of 5-50 nm; in some embodiments, 10-30 nm.

In some embodiments, the second metal has a thermal conductivity less than 1.0 watts/cm° C. In some embodiments, the second metal has a heat of fusion that is greater than the heat of fusion of the first metal. In some embodiments, the second metal has a heat of fusion greater than 14 kJ/mol.

In some embodiments, the second metal is chromium, nickel, palladium, titanium, or germanium.

In some embodiments, the second metal is chromium, which has an electrical conductivity of 7.7×10⁴ Scm⁻¹ and a thermal conductivity of 0.91 watts/cm° C.

In some embodiments, the second metal is nickel, which has an electrical conductivity of 1.4×10⁵ Scm⁻¹ and a thermal conductivity of 0.90 watts/cm° C.

In some embodiments, the second metal is palladium, which has an electrical conductivity of 9.5×10⁴ Scm⁻¹ and a thermal conductivity of 0.72 watts/cm° C.

In some embodiments, the second metal is titanium, which has an electrical conductivity of 2.3×10⁴ Scm⁻¹ and a thermal conductivity of 0.22 watts/cm° C.

In some embodiments, the second metal is germanium, which has an electrical conductivity of 0 Scm⁻¹ and a thermal conductivity of 0.60 watts/cm° C.

In some embodiments, layer M2 consists essentially of chromium, nickel, palladium, titanium, or germanium.

In some embodiments, layer M2 has a thickness in the range of 0.1-5 nm; in some embodiments, 0.5-5 nm.

Layers M1 and M2 can be formed by any conventional deposition technique for forming layers, including vapor deposition, liquid deposition (continuous and discontinuous techniques), and thermal transfer. In some embodiments, layers M1 and M2 are formed by a vapor deposition process. Such processes are well known in the art.

c. Additional Layers

The composite electrode may optionally include one or more of a second layer M2, a layer M3, and a layer M4.

Layer M3 is a conductive inorganic layer which is at least partially transmissive to visible light. In some embodiments, layer M3 comprises indium-tin-oxide, indium-zinc-oxide, aluminum-tin-oxide, aluminum-zinc-oxide, or zirconium-tin-oxide. In some embodiments, layer M3 consists essentially of indium-tin-oxide, indium-zinc-oxide, aluminum-tin-oxide, aluminum-zinc-oxide, or zirconium-tin-oxide. In some embodiments, layer M3 has a thickness in the range of 30-200 nm; in some embodiments, 50-150 nm.

Layer M3 can be formed by any conventional deposition technique for forming layers, including vapor deposition, liquid deposition (continuous and discontinuous techniques), and thermal transfer. In some embodiments, layer M3 is formed by a vapor deposition process. Such processes are well known in the art.

Layer M4 comprises an organic hole injection material. Hole injection materials may be polymers, oligomers, or small molecules. Examples of hole injection materials include, but are not limited to, conductive polymers doped with polymeric protonic acids, such as polyaniline (PANI) or polyethylenedioxythiophene (PEDOT) doped with poly(styrenesulfonic acid), poly(2-acrylamido-2-methyl-1-propanesulfonic acid), and the like; small molecules such as tetrafluorotetracyanoquinodimethane, perylene-3,4,9,10-tetracarboxylic-3,4,9,10-dianhydride, perylene-3,4,9,10-tetracarboxylic-3,4,9,10-diimide, naphthalene tetracarboxylic diimide, and hexaazatriphenylene hexacarbonitrile. In some embodiments, the hole injection material is a conducting polymer doped with a colloid-forming polymeric sulfonic acid. Such materials have been described in, for example, published U.S. patent applications US 2004/0102577, US 2004/0127637, and US 2005/0205860, and published PCT application WO 2009/018009.

In some embodiments, layer M4 comprises hexaazatriphenylene hexacarbonitrile or a conducting polymer doped with a colloid-forming polymeric sulfonic acid. In some embodiments, layer M4 consists essentially of hexaazatriphenylene hexacarbonitrile or a conducting polymer doped with a colloid-forming polymeric sulfonic acid.

In some embodiments, layer M4 has a thickness in the range of 10-300 nm; in some embodiments, 50-200 nm.

Layer M4 can be formed by any conventional deposition technique, including vapor deposition, liquid deposition (continuous and discontinuous techniques), and thermal transfer. Continuous liquid deposition techniques, include but are not limited to, spin coating, gravure coating, curtain coating, dip coating, slot-die coating, spray coating, and continuous nozzle coating. Discontinuous liquid deposition techniques include, but are not limited to, ink jet printing, gravure printing, and screen printing.

When the single layer A1 is present, the composite electrode may have any combination of the layers shown below in the order given.

M3/M2/A1/M2/M4

provided that at least A1 is present.

When a bilayer of M1 and M2 is present, the composite electrode may have any combination of the layers shown below in the order given.

M3/M2/M1/M2/M4

provided that at least one M1 layer and one M2 layer are present.

### 3. Electronic Device

Organic electronic devices that may benefit from having the composite electrode as described herein include, but are not limited to, (1) devices that convert electrical energy into radiation (e.g., a light-emitting diode, light emitting diode display, lighting device, luminaire, or diode laser), (2) devices that detect signals through electronics processes (e.g., photodetectors, photoconductive cells, photoresistors, photoswitches, phototransistors, phototubes. IR detectors, biosensors), (3) devices that convert radiation into electrical energy, (e.g., a photovoltaic device or solar cell), and (4) devices that include one or more electronic components that include one or more organic semi-conductor layers (e.g., a transistor or diode). Other uses for the compositions according to the present invention include coating materials for memory storage devices, antistatic films, biosensors, electrochromic devices, solid electrolyte capacitors, energy storage devices such as a rechargeable battery, and electromagnetic shielding applications.

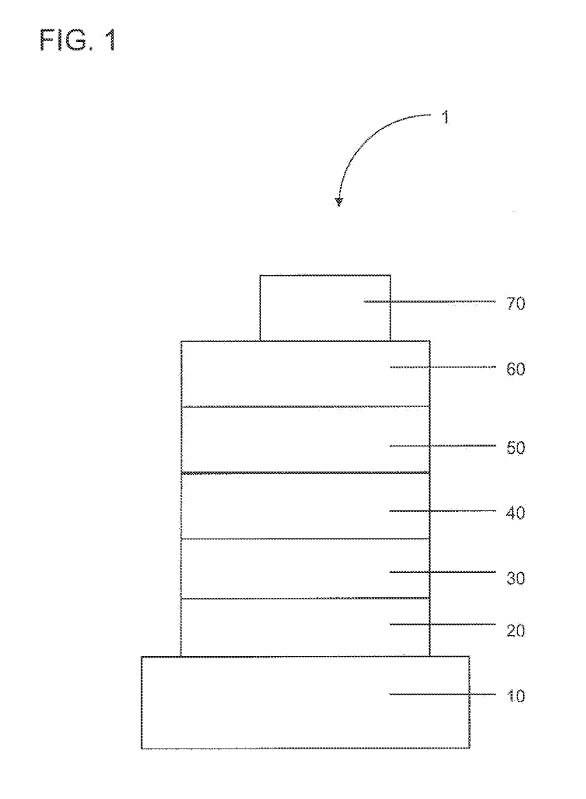

One example of an organic electronic device is an organic light-emitting diode (“OLED”). OLED devices generally include a photoactive layer between two electrical contact layers, which are an anode and a cathode. A typical device structure is illustrated schematically in FIG. 1. Device 1 includes substrate 10, anode 20, optional hole transport layer 30, photoactive layer 40, optional electron transport layer 500, optional electron injection layer 60, and cathode 70. In some embodiments, the photoactive layer is pixelated with subpixels emitting different colors to form a display. In some embodiments, the subpixels are red light-emitting, green light-emitting, and blue light-emitting. In some embodiments, the photoactive layer is not pixelated to form, for example, a lighting device.

In most cases, the anode is made of indium tin oxide (“ITO”). However, ITO-based devices have limitations in both their efficiencies and colors. First, the photons emitted in the desired forward direction are, in general, limited to about 20-25% of the total number of photons generated in the device. The rest of the photons are either absorbed in the device or wave-guided out from the edges of the device. The efficiency requirement of the next generation display is much higher than the theoretical limits achievable from these ITO-based devices. For example, the near term target for red is 45 cd/A, but current ITO-based red devices can only reach about 25 cd/A. To extract trapped photons, conventional outcoupling techniques, such as cover films with scattering particles or pyramidal structures, tend to reduce the display resolution.

Second, next generation OLED displays require more saturated colors than can be delivered by current ITO-based devices. For example, the NTSC targets for green and blue are CIExy of (0.21, 0.71) and CIExy of (0.14, 0.08), respectively. “CIExy” refers to the x and y color coordinates, according to the C.I.E. chromaticity scale (Commission Internationale de L'Eclairage, 1931). These coordinates cannot be achieved by conventional bottom-emitting OLED structures using an ITO anode with the current material set.

The composite electrode described above can be used as the anode in an OLED device.

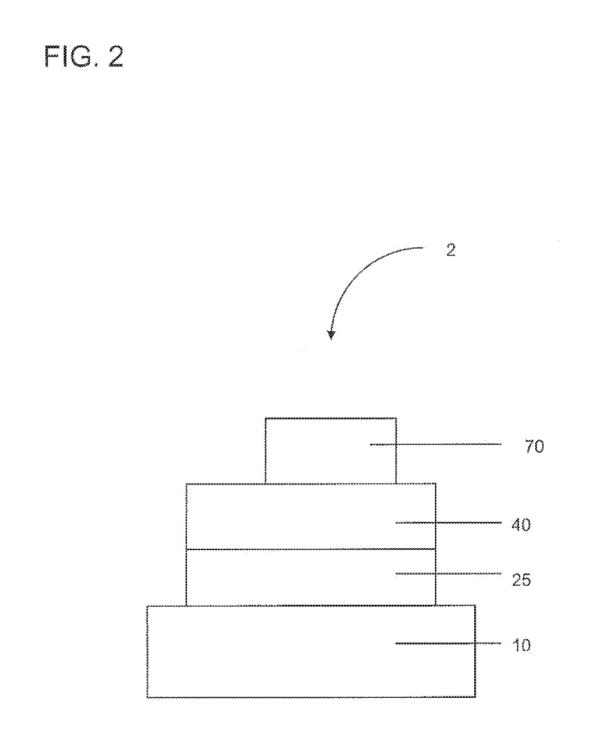

In some embodiments, the anode is a composite electrode which is a single layer A1. This is illustrated schematically in FIG. 2. In this figure, device 2 has substrate 10, the composite electrode as anode 25 which is A1, photoactive layer 40 and cathode 70. In this figure, and in all subsequent figures, the other device layers are not shown, but may be present as discussed above. In this figure and in all subsequent figures, the substrate is shown as 10, the photoactive layer is shown as 40 and the cathode is shown as 70.

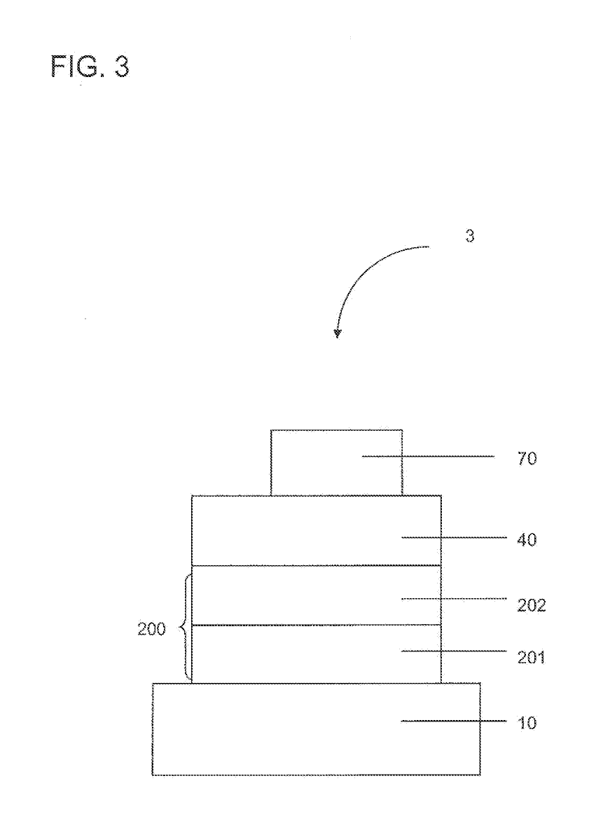

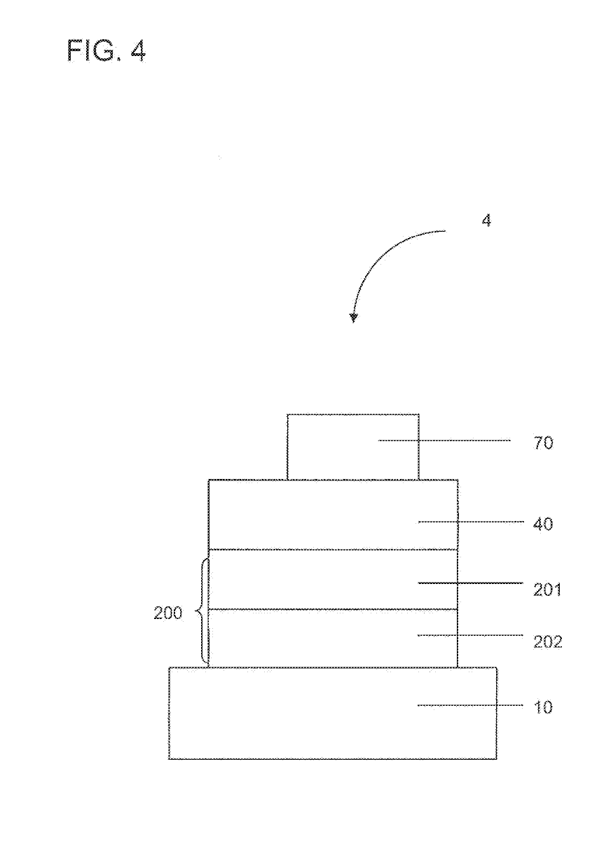

In some embodiments, the anode is a composite electrode which comprises a bilayer. This is illustrated schematically in FIGS. 3 and 4. Device 3 in FIG. 3, has a composite anode 200 with a first layer 201 and a second layer 202. Layer 201 is M1 and layer 202 is M2. It should be noted that in all the figures the layers are not drawn to scale and the relative thicknesses of the layers are not shown.

Device 4 in FIG. 4, has a composite anode 200 with the layers reversed. Layer 202, which is M2, is directly on the substrate 100 and layer 201, which is M1, is over and in direct physical contact with layer 202.

In some embodiments, one or more additional layers may be present including a layer M2, a layer M3, and a layer M4.

When layer M2 is present, it is in direct physical contact with layer M1 or layer A1.

When layer M3 is present it is adjacent the substrate. By this it is meant that layer M3 on the substrate side of the composite anode, but not necessarily in direct physical contact with the substrate. In some embodiments, layer M3 is in physical contact with the substrate.

When layer M4 is present it is adjacent the photoactive layer. By this it is meant that layer M4 on the photoactive layer side of the composite anode, but not necessarily in direct physical contact with the substrate. In some embodiments, there is a hole transport layer between layer M4 and the photoactive layer.

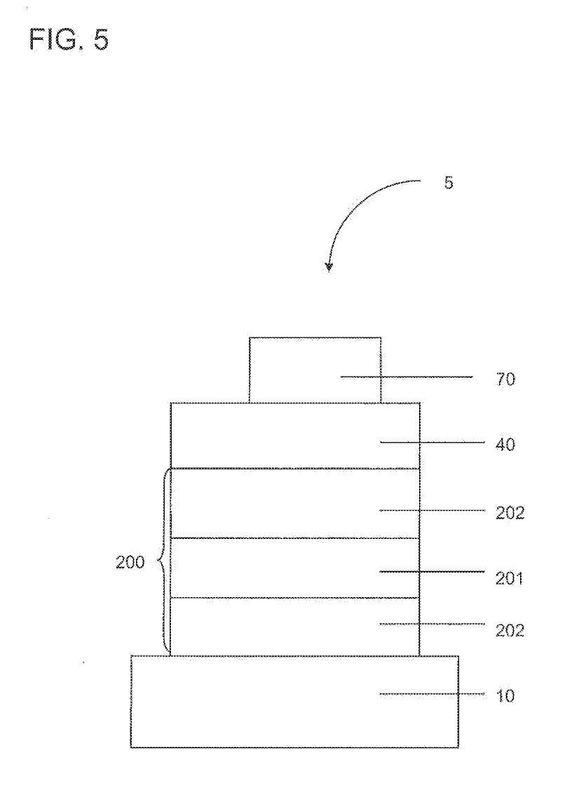

FIGS. 5-13 illustrate embodiments in which the one or more additional layers are present in the composite electrode.

Device 5, in FIG. 5, has a composite anode 200 with layers 202, 201, and 202, in that order. Layer 202 is M2, layer 201 is M1, and the second 202 layer is M2.

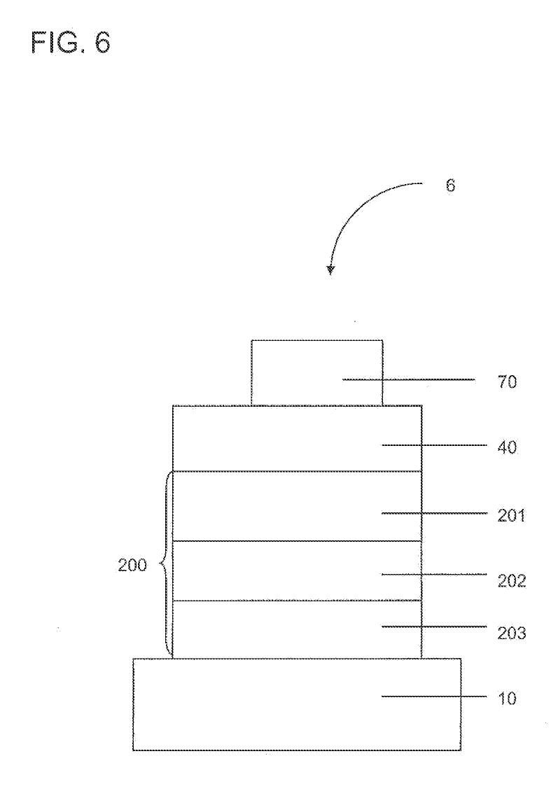

Device 6, in FIG. 6, has a composite anode 200 with layers 203, 202, and 201, in that order. Layer 203 is M3, layer 202 is M2, and layer 201 is M1.

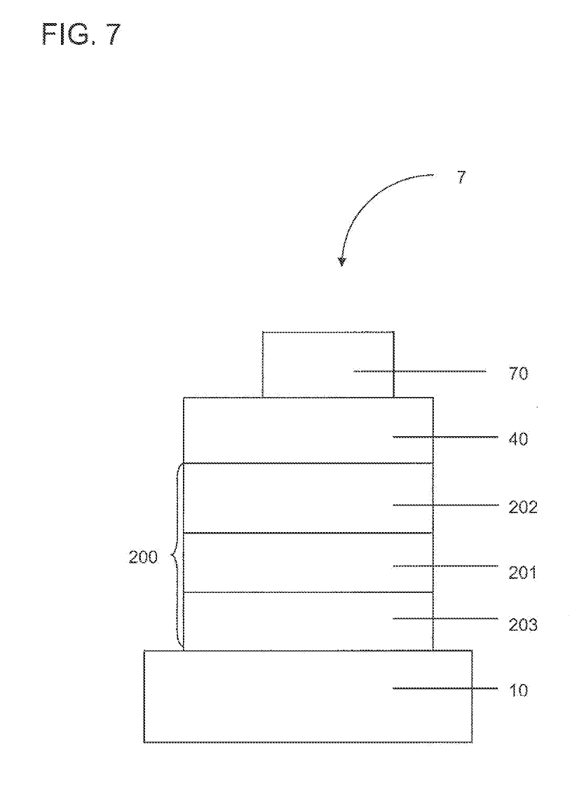

Device 7, in FIG. 7, has a composite anode 200 with layers 203, 201, and 202, in that order. Layer 203 is M3, layer 201 is M1, and layer 202 is M2.

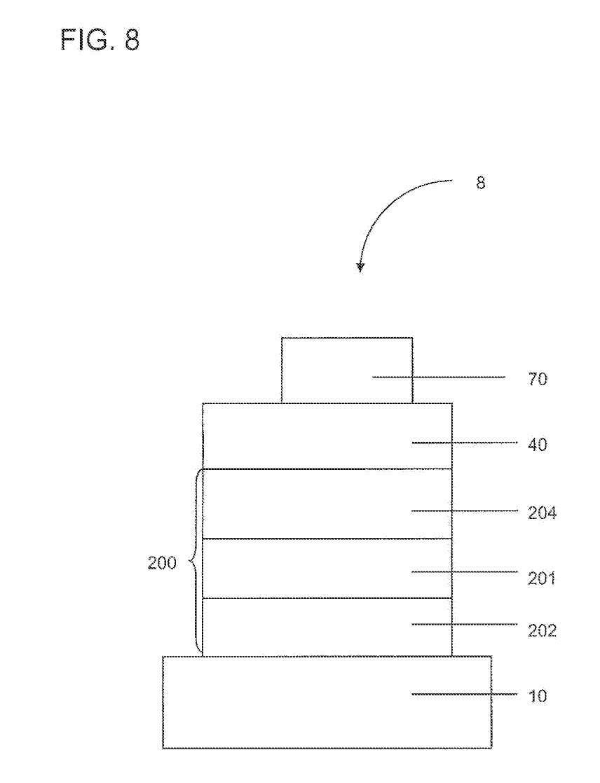

Device 8, in FIG. 8, has a composite anode 200 with layers 202, 201, and 204 in that order. Layer 202 is M2, layer 201 is M1, and layer 204 is M4.

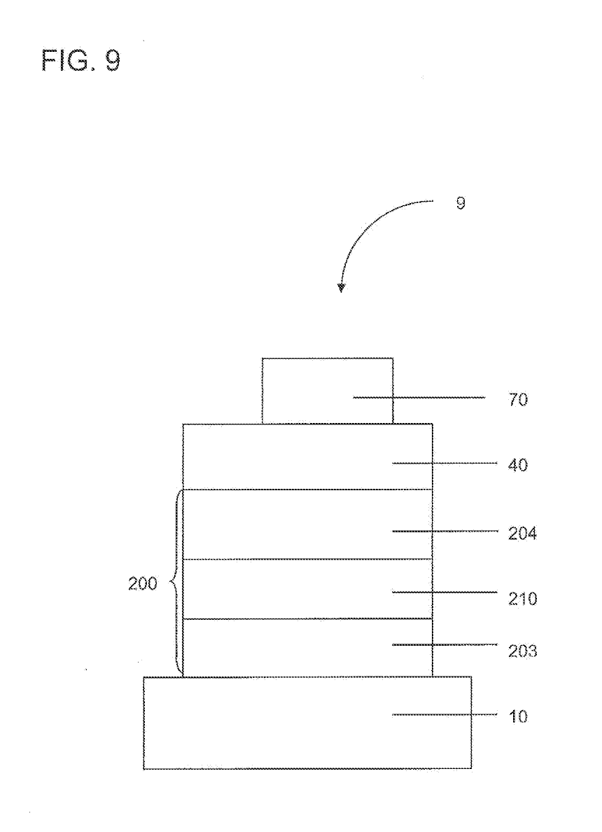

Device 9, in FIG. 9, has a composite anode 200 with layers 203, 210, and 204 in that order. Layer 203 is M3, layer 210 is A1, and layer 204 is M4.

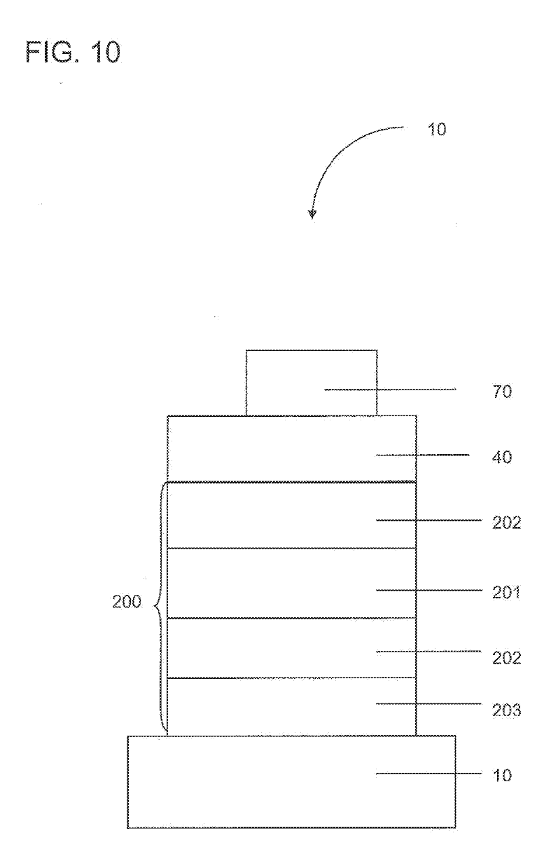

Device 10, in FIG. 10, has a composite anode 200 with layers 203, 202, 201, and 202 in that order. Layer 203 is M3, layer 202 is M2, layer 201 is M1, and second layer 202 is M2.

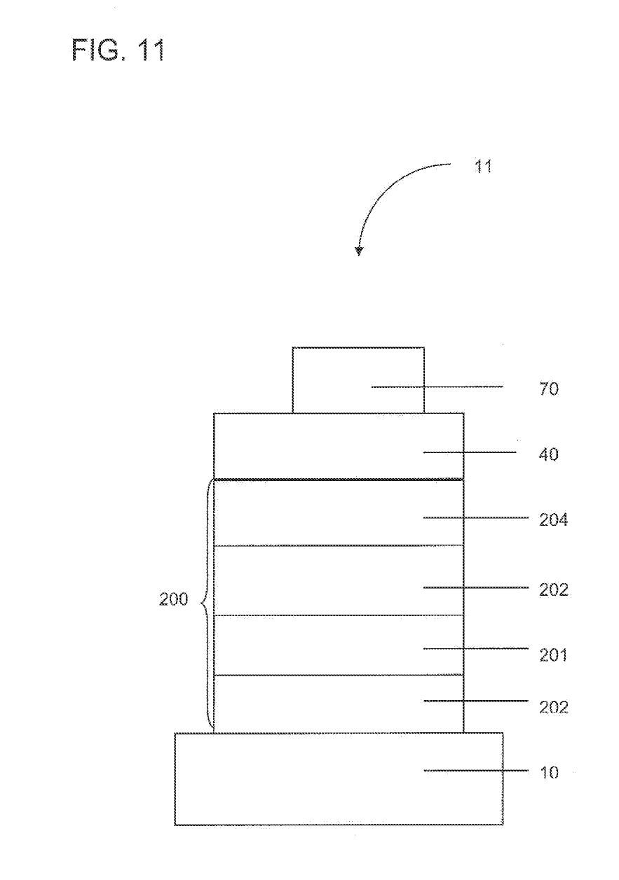

Device 11, in FIG. 11 has a composite anode 200 with layers 202, 201, 202, and 204 in that order. Layer 202 is M2, layer 201 is M1, the second layer 202 is M2, and layer 204 is M4.

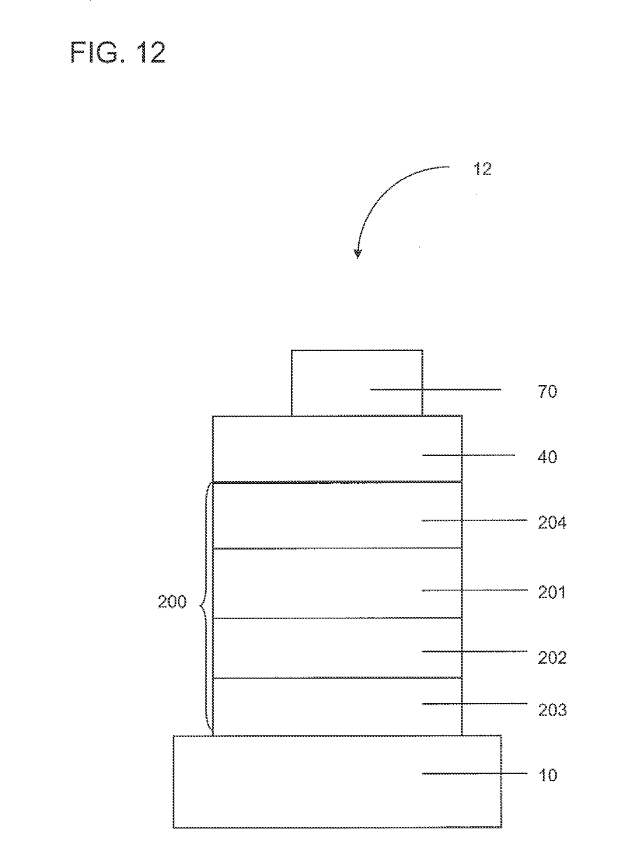

Device 12, in FIG. 12, has a composite anode 200 with layers 203, 202, 201, and 204 in that order. Layer 203 is M3, layer 202 is M2, layer 201 is M1, and layer 204 is M4.

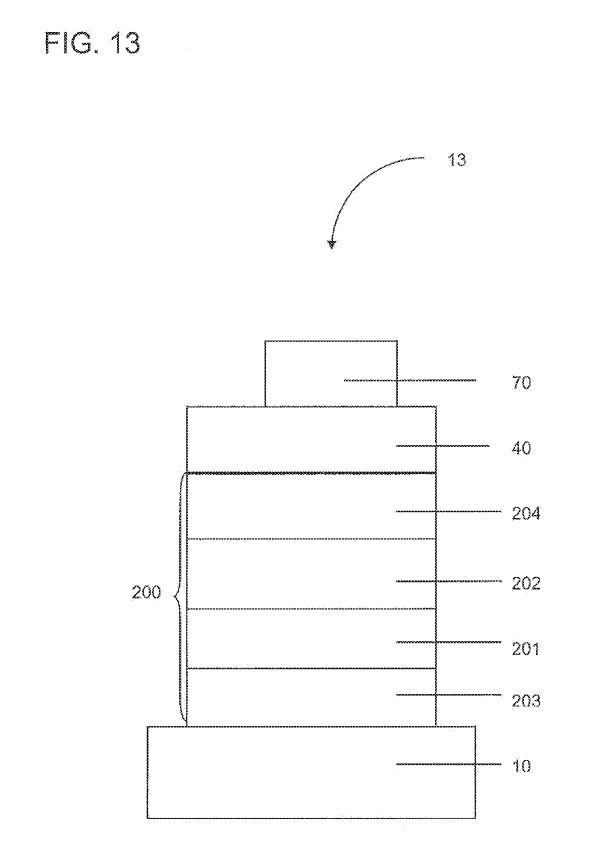

Device 13, in FIG. 13, has a composite anode 200 with layers 203, 201, 202, and 204 in that order. Layer 203 is M3, layer 201 is M1, layer 202 is M2, and layer 204 is M4.

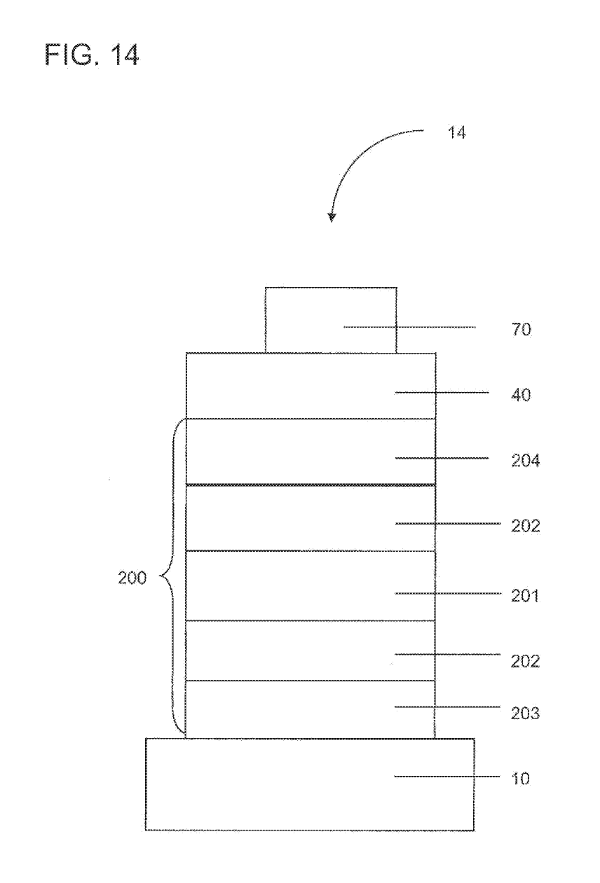

Device 14, in FIG. 14, has a composite anode 200 with layers 203, 202, 201, 202, and 204, in that order. Layer 203 is M3, layer 202 is M2, layer 201 is M1, the second layer 202 is M2, and layer 204 is M4.

Other composite electrodes with combinations of layers M1 through M4 are also possible.

a. Other Device Layers

The other layers in the device can be made of any materials that are known to be useful in such layers.

The substrate 10 is a base material that can be either rigid or flexible. The substrate may include one or more layers of one or more materials, which can include, but are not limited to, glass, polymer, metal or ceramic materials or combinations thereof. The substrate may or may not include electronic components, circuits, or conductive members.

Examples of hole transport materials for optional layer 30 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules are: N,N′-diphenyl-N,N′-bis(3-methylphenyl)-[1,1′-biphenyl]-4,4′-diamine (TPD), 1,1-bis[(di-4-tolylamino)phenyl]cyclohexane (TAPC), N,N′-bis(4-methylphenyl)-N,N′-bis(4-ethylphenyl)-[1,1′-(3,3′-dimethyl)biphenyl]-4,4′-diamine (ETPD), tetrakis-(3-methylphenyl)-N,N,N′,N′-2,5-phenylenediamine (PDA), a-phenyl-4-N,N-diphenylaminostyrene (TPS), p-(diethylamino)benzaldehyde diphenylhydrazone (DEH), triphenylamine (TPA), bis[4-(N,N-diethylamino)-2-methylphenyl](4-methylphenyl)methane (MPMP), 1-phenyl-3-[p-(diethylamino)styryl]-5-[p-(diethylamino)phenyl]pyrazoline (PPR or DEASP), 1,2-trans-bis(9H-carbazol-9-yl)cyclobutane (DCZB), N,N,N′,N′-tetrakis(4-methylphenyl)-(1,1′-biphenyl)-4,4′-diamine (TTB), N,N′-bis(naphthalen-1-yl)-N,N′-bis-(phenyl)benzidine (□-NPB), and porphyrinic compounds, such as copper phthalocyanine. Commonly used hole transporting polymers are polyvinylcarbazole, (phenylmethyl)-polysilane, and polyaniline. It is also possible to obtain hole transporting polymers by doping hole transporting molecules such as those mentioned above into polymers such as polystyrene and polycarbonate. In some cases, triarylamine polymers are used, especially triarylamine-fluorene copolymers. In some cases, the polymers and copolymers are crosslinkable. In some embodiments, the hole transport layer further comprises a p-dopant. In some embodiments, the hole transport layer is doped with a p-dopant. Examples of p-dopants include, but are not limited to, tetrafluorotetracyanoquinodimethane (F4-TCNQ) and perylene-3,4,9,10-tetracarboxylic-3,4,9,10-dianhydride (PTCDA).

Depending upon the application of the device, the photoactive layer 400 can be a light-emitting layer that is activated by an applied voltage (such as in a light-emitting diode or light-emitting electrochemical cell), a layer of material that responds to radiant energy and generates a signal with or without an applied bias voltage (such as in a photodetector). In one embodiment, the electroactive layer comprises an organic electroluminescent (“EL”) material. Any EL material can be used in the devices, including, but not limited to, small molecule organic fluorescent compounds, luminescent metal complexes, conjugated polymers, and mixtures thereof. Examples of fluorescent compounds include, but are not limited to, chrysenes, pyrenes, perylenes, rubrenes, coumarins, anthracenes, thiadiazoles, derivatives thereof, and mixtures thereof. Examples of metal complexes include, but are not limited to, metal chelated oxinoid compounds, such as tris(8-hydroxyquinolato)aluminum (Alq3): cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. In some cases the small molecule fluorescent or organometallic materials are deposited as a dopant with a host material to improve processing and/or electronic properties. Examples of conjugated polymers include, but are not limited to poly(phenylenevinylenes), polyfluorenes, poly(spirobifluorenes), polythiophenes, poly(p-phenylenes), copolymers thereof, and mixtures thereof.

In some embodiments, photoactive layer 40 comprises an electroluminescent material in a host material. In some embodiments, a second host material is also present. Examples of host materials include, but are not limited to, chrysenes, phenanthrenes, triphenylenes, phenanthrolines, naphthalenes, anthracenes, quinolines, isoquinolines, quinoxalines, phenylpyridines, benzodifurans, metal quinolinate complexes, and combinations thereof.

Optional layer 500 can function both to facilitate electron transport, and also serve as a hole injection layer or confinement layer to prevent quenching of the exciton at layer interfaces. Preferably, this layer promotes electron mobility and reduces exciton quenching. Examples of electron transport materials which can be used in the optional electron transport layer 500, include metal chelated oxinoid compounds, including metal quinolate derivatives such as tris(8-hydroxyquinolato)aluminum (AlQ), bis(2-methyl-8-quinolinolato)(p-phenylphenolato) aluminum (BAlq), tetrakis-(8-hydroxyquinolato)hafnium (HQ) and tetrakis-(8-hydroxyquinolato)zirconium (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); triazines; fullerenes; and mixtures thereof. In some embodiments, the electron transport material is selected from the group consisting of metal quinolates and phenanthroline derivatives. In some embodiments, the electron transport layer further comprises an n-dopant. N-dopant materials are well known. The n-dopants include, but are not limited to. Group 1 and 2 metals; Group 1 and 2 metal salts, such as LiF, CsF, and Cs₂CO₃; Group 1 and 2 metal organic compounds, such as Li quinolate; and molecular n-dopants, such as leuco dyes, metal complexes, such as W₂(hpp)₄ where hpp=1,3,4,6,7,8-hexahydro-2H-pyrimido-[1,2-a]-pyrimidine and cobaltocene, tetrathianaphthacene, bis(ethylenedithio)tetrathiafulvalene, heterocyclic radicals or diradicals, and the dimers, oligomers, polymers, dispiro compounds and polycycles of heterocyclic radical or diradicals.

The cathode 70, is an electrode that is particularly efficient for injecting electrons or negative charge carriers. The cathode can be any metal or nonmetal having a lower work function than the anode. Materials for the cathode can be selected from alkali metals of Group 1 (e.g., Li, Cs), the Group 2 (alkaline earth) metals, the Group 12 metals, including the rare earth elements and lanthanides, and the actinides. Materials such as aluminum, indium, calcium, barium, samarium and magnesium, as well as combinations, can be used. Li-containing organometallic compounds, LiF, Li₂O, Cs-containing organometallic compounds, CsF, Cs₂O, and Cs₂CO₃ can also be deposited between the organic layer and the cathode layer to lower the operating voltage. This optional layer may be referred to as an electron injection layer 60. In some embodiments, the material deposited for the electron injection layer reacts with the underlying electron transport layer and/or the cathode and does not remain as a measurable layer.

It is known to have other layers in organic electronic devices. The choice of materials for each of the component layers is preferably determined by balancing the positive and negative charges in the emitter layer to provide a device with high electroluminescence efficiency. It is understood that each functional layer can be made up of more than one layer.

In one embodiment, the different layers have the following range of thicknesses: composite anode, 500-5000 Å, in one embodiment 1000-2000 Å; hole transport layer, 50-2000 Å, in one embodiment 200-1000 Å; photoactive layer, 10-2000 Å, in one embodiment 100-1000 Å; electron transport layer, 50-500 Å, in one embodiment 100-300 Å; cathode, 200-10000 Å, in one embodiment 300-5000 Å. The desired ratio of layer thicknesses will depend on the exact nature of the materials used.

The device layers can be formed by any deposition technique, or combinations of techniques, including vapor deposition, liquid deposition, and thermal transfer. Conventional vapor deposition techniques can be used, such as thermal evaporation, chemical vapor deposition, and the like. The organic layers can be applied from solutions or dispersions in suitable solvents, using conventional coating or printing techniques, including but not limited to spin-coating, dip-coating, roll-to-roll techniques, ink-jet printing, continuous nozzle printing, screen-printing, gravure printing and the like.

For liquid deposition methods, a suitable solvent for a particular compound or related class of compounds can be readily determined by one skilled in the art. For some applications, it is desirable that the compounds be dissolved in non-aqueous solvents. Such non-aqueous solvents can be relatively polar, such as C₁ to C₂₀ alcohols, ethers, and acid esters, or can be relatively non-polar such as C₁ to C₁₂ alkanes or aromatics such as toluene, xylenes, trifluorotoluene and the like. Other suitable liquids for use in making the liquid composition, either as a solution or dispersion as described herein, comprising the new compounds, includes, but not limited to, chlorinated hydrocarbons (such as methylene chloride, chloroform, chlorobenzene), aromatic hydrocarbons (such as substituted and non-substituted toluenes and xylenes), including trifluorotoluene), polar solvents (such as tetrahydrofuran (THP), N-methylpyrrolidone) esters (such as ethylacetate) alcohols (isopropanol), keytones (cyclopentatone) and mixtures thereof. Suitable solvents for electroluminescent materials have been described in, for example, published PCT application WO 2007/145979.

In some embodiments, following deposition of the composite anode, as described above, the device is fabricated by liquid deposition of the hole transport layer and the photoactive layer, and by vapor deposition of the electron transport layer, an electron injection layer and the cathode.

It is understood that the efficiency of devices made with the new compositions described herein, can be further improved by optimizing the other layers in the device. For example, more efficient cathodes such as Ca, Ba or LiF can be used. Shaped substrates and novel hole transport materials that result in a reduction in operating voltage or increase quantum efficiency are also applicable. Additional layers can also be added to tailor the energy levels of the various layers and facilitate electroluminescence.

In one embodiment, the device has the following structure, in order: composite anode, hole transport layer, photoactive layer, electron transport layer, electron injection layer, cathode.

Although methods and materials similar or equivalent to those described herein can be used in the practice or testing of the present invention, suitable methods and materials are described below. In addition, the materials, methods, and examples are illustrative only and not intended to be limiting. All publications, patent applications, patents, and other references mentioned herein are incorporated by reference in their entirety.

### EXAMPLES

The concepts described herein will be further described in the following examples, which do not limit the scope of the invention described in the claims.

### Materials

Compound 1 is made from an aqueous dispersion of an electrically conductive polymer and a polymeric fluorinated sulfonic acid. Such materials have been described in, for example, published U.S. patent applications US 2004/0102577, US 2004/0127637, and US 2005/0205860,
Compound 2 is an N-aryl-indolocarbazole
Compound 3 is a triarylamine polymer. Such materials have been described in, for example, published PCT application WO 2009/067419.
Compound 4 is a tris cyclometallated iridium complex with three substituted phenypyridine ligands
Compound 5 is a bis cyclometallated iridium complex with two substituted phenyl-isoquinoline ligands and one beta-dienolate ligand.
Compound 6 is bis(diarylamino)chrysene
Compound 7 is an indolocarbazole having a triazine substituent
Compound 8 is a metal quinolate complex
Compound 9 is an arylaminochrysene
Compound 10 is a diarylanthracene
Compound 11 is a tris cyclometallated iridium complex with three substituted phenyl-isoquinoline ligands
Compound 12 is a aryl-substituted triphenylene
Compound 13 is a metal quinolate complex
Compound 14 is a phenanthroline derivative
Compound 15 is a tris cyclometallated iridium complex with three substituted phenylpyridine ligands
NPB is shown below

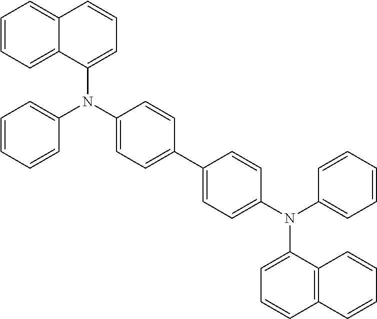 [SMILES: c1ccc(N(c2ccc(-c3ccc(N(c4ccccc4)c4cccc5ccccc45)cc3)cc2)c2cccc3ccccc23)cc1]

HAT-CN is shown below

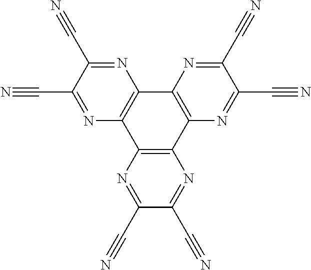 [SMILES: N#Cc1nc2c3nc(C#N)c(C#N)nc3c3nc(C#N)c(C#N)nc3c2nc1C#N]

The cavity effects for ITO-based devices are very different from those for the devices with the composite anode. Thus, the devices of the examples and the devices of the comparative examples are optimized with slight differences in the thicknesses of some of the device layers. The comparison between the examples and the comparative examples is then between optimal (or near optimal) device structures.

### Example 1 and Comparative Example A

This example illustrates the performance of a device with green emission color and having the new composite anode.

The photoactive layer in both devices had 16% by weight of green-emissive dopant Compound 4. The host was Compound 7.

In Example 1, the anode had the configuration shown in FIG. 8, Layer 202 was M2, a 1.5 nm layer of Cr; layer 201 was M1, a 15 nm layer of Ag; and layer 204 was M4, a 60 nm layer of Compound 1.

In Comparative Example A, the anode was an 80 nm layer of ITO. The anode was overcoated with a hole injection layer of 61 nm of Compound 1.

The devices were prepared on a glass substrate. Compound 1 was deposited by spin coating from an aqueous dispersion. All other layers were applied by evaporative deposition. The device layers are summarized in Table 1.

TABLE 1
Device Composition

| | Example 1 | | Comparative Example A | |
|---|---|---|---|---|
| Device | | Thickness | | Thickness |
| Layer | Material | (nm) | Material | (nm) |
| anode | Cr | 1.5 | ITO | 80 |
| | Ag | 15 | | |
| | Cmpd. 1 | 60 | | |
| HIL | — | | Cmpd. 1 | 61 |
| HTL | Cmpd. 2 | 15 | Cmpd. 2 | 20 |
| PhL | 16% Cmpd. 4 | 45 | 16% Cmpd. 4 in | 45 |
| | in Cmpd. 7 | | Cmpd. 7 | |
| ETL 1 | Cmpd. 12 | 5 | Cmpd. 12 | 5 |
| ETL 2 | Cmpd. 13 | 5 | Cmpd. 13 | 15 |
| EIL | LiF | 1 | LiF | 1 |
| cathode | Al | 100 | Al | 100 |

HIL = hole injection layer;
HTL = hole transport layer;
PhL = photoactive layer;
ETL = electron transport layer;
EIL = electron injection layer (as deposited).

The OLED samples were characterized by measuring their (1) current-voltage (I-V) curves, (2) electroluminescence radiance versus voltage, and (3) electroluminescence spectra versus voltage. All three measurements were performed at the same time and controlled by a computer. The current efficiency of the device at a certain voltage is determined by dividing the electroluminescence radiance of the LED by the current density needed to run the device. The unit is a cd/A. The color coordinates were determined using either a Minolta CS-100 meter or a Photoresearch PR-705 meter. The results are shown in Table 2.

TABLE 2
Device Results

| | Efficiency | | Voltage |
|---|---|---|---|
| Device | (cd/A) | CIE (x, y) | (V) |
| Example 1 | 103 | 0.25, 0.71 | 3.5 |
| Comp. Ex. A | 83 | 0.34, 0.63 | 4.8 |

All measurements at 1000 nits.
“CIExy” refers to the x and y color coordinates, according to the C.I.E. chromaticity scale (Commission Internationale de L'Eclairage, 1931).

It can be seen from Table 2, that the device with the new composite anode has higher efficiency and lower voltage. The color coordinates in the device with the new composite anode are closer to the NTSC green standard of (0.210, 0.710).

### Example 2 and Comparative Example A

This example illustrates the performance of a device with green emission color and having the new composite anode.

The photoactive layer in both devices had 16% by weight of green-emissive dopant Compound 4. The host was Compound 7.

In Example 2, the anode had the configuration shown in FIG. 5. Layer 202 was M2, a 1 nm layer of Ni; layer 201 was M1, a 15 nm layer of Ag; Layer 202 was M2, a 1 nm layer of Ni, and layer 204 was M4, a 60 nm layer of Compound 1.

In Comparative Example A, the anode was a 80 nm layer of ITO. The anode was overcoated with a hole injection layer of 61 nm of Compound 1.

The devices were prepared on a glass substrate. Compound 1 was deposited by spin coating from an aqueous dispersion. All other layers were applied by evaporative deposition. The device layers are summarized in Table 3.

TABLE 3
Device Composition

| | Example 2 | | Comparative Example A | |
|---|---|---|---|---|
| Device | | Thickness | | Thickness |
| Layer | Material | (nm) | Material | (nm) |
| anode | Ni | 1.0 | ITO | 80 |
| | Ag | 15 | | |
| | Ni | 1.0 | | |
| | Cmpd. 1 | 61 | | |
| HIL | — | | Cmpd. 1 | 61 |
| HTL | Cmpd. 2 | 10 | Cmpd. 2 | 20 |
| PhL | 16% Cmpd. 4 | 45 | 16% Cmpd. 4 in | 45 |
| | in Cmpd. 7 | | Cmpd. 7 | |
| ETL 1 | Cmpd. 12 | 5 | Cmpd. 12 | 5 |
| ETL 2 | Cmpd. 13 | 5 | Cmpd. 13 | 15 |
| EIL | LiF | 1 | LiF | 1 |
| cathode | Al | 100 | Al | 100 |

HIL = hole injection layer;
HTL = hole transport layer;
PhL = photoactive layer;
ETL = electron transport layer;
EIL = electron injection layer (as deposited).

The OLED samples were characterized as described above for Example 1. The results are shown in Table 4.

TABLE 4
Device Results

| | Efficiency | | Voltage |
|---|---|---|---|
| Device | (cd/A) | CIE (x, y) | (V) |
| Example 2 | 115 | 0.29, 0.68 | 3.4 |
| Comp. Ex. A | 83 | 0.34, 0.63 | 4.8 |

All measurements at 1000 nits.
“CIExy” refers to the x and y color coordinates, according to the C.I.E. chromaticity scale (Commission Internationale de L'Eclairage, 1931).

It can be seen from Table 4, that the device with the new composite anode has higher efficiency and lower voltage. The color coordinates in the device with the new composite anode are closer to the NTSC green standard of (0.210, 0.710).

### Example 3 and Comparative Example B

This example illustrates the performance of a device with red emission color and having the new composite anode.

The photoactive layer had 8% by weight Compound 5 as the red-emissive dopant. The host was a combination of Compound 8 and NPB in a 9:1 weight ratio.

In Example 3, the anode had the configuration shown in FIG. 8. Layer 202 was M2, a 1.5 nm layer of Cr; layer 201 was M1, a 15 nm layer of Ag; and layer 204 was M4, a 60 nm layer of Compound 1.

In Comparative Example B, the anode was an 80 nm layer of ITO. The anode was overcoated with a hole injection layer of 67 nm of Compound 1.

The devices were prepared on a glass substrate. Compound 1 was deposited by spin coating from an aqueous dispersion. All other layers were applied by evaporative deposition. The device layers are summarized in Table 5.

TABLE 5
Device Composition

| | Example 3 | | Comparative Example B | |
|---|---|---|---|---|
| Device | | Thickness | | Thickness |
| Layer | Material | (nm) | Material | (nm) |
| anode | Cr | 1.5 | ITO | 80 |
| | Ag | 15 | | |
| | Cmpd. 1 | 60 | | |
| HIL | — | | Cmpd. 1 | 67 |
| HTL | NPB | 20 | NPB | 30 |
| PhL | 8% Cmpd. 5 in | 50 | 8% Cmpd. 5 in | 40 |
| | 9:1 Cmpd. 8:NPB | | 9:1 Cmpd. 8:NPB | |
| ETL | Cmpd. 13 | 30 | Cmpd. 13 | 30 |
| EIL | CsF | 1 | CsF | 1 |
| cathode | Al | 100 | Al | 100 |

HIL = hole injection layer;
HTL = hole transport layer:
PhL = photoactive layer;
ETL = electron transport layer;
EIL = electron injection layer (as deposited).

The OLED samples were characterized as described above for Example 1. The results are shown in Table 6.

TABLE 6
Device Results

| | Efficiency | | Voltage |
|---|---|---|---|
| Device | (cd/A) | CIE (x, y) | (V) |
| Example 3 | 40.5 | 0.665, 0.335 | 3.7 |
| Comp. Ex. B | 21 | 0.655, 0.345 | 4.8 |

All measurements at 1000 nits.
“CIExy” refers to the x and y color coordinates, according to the C.I.E. chromaticity scale (Commission Internationale de L'Eclairage, 1931).

It can be seen from Table 6, that the device with the new composite anode has higher efficiency and lower voltage. The color coordinates in the device with the new composite anode are closer to the NTSC red standard of (0.670, 0.330).

### Example 4 and Comparative Example B

This example illustrates the performance of a device with red emission color and having the new composite anode.

The photoactive layer had 8% by weight Compound 5 as the red-emissive dopant. The host was a combination of Compound 8 and NPB in a 9:1 weight ratio.

In Example 4, the anode had the configuration shown in FIG. 8. Layer 202 was M2, a 1.0 nm layer of Cr: layer 201 was M1, a 25 nm layer of Au; and layer 204 was M4, a 60 nm layer of Compound 1.

In Comparative Example B, the anode was an 80 nm layer of ITO. The anode was overcoated with a hole injection layer of 67 nm of Compound 1.

The devices were prepared on a glass substrate. Compound 1 was deposited by spin coating from an aqueous dispersion. All other layers were applied by evaporative deposition. The device layers are summarized in Table 7.

TABLE 7
Device Composition

| | Example 4 | | Comparative Example B | |
|---|---|---|---|---|
| Device | | Thickness | | Thickness |
| Layer | Material | (nm) | Material | (nm) |
| anode | Cr | 1.0 | ITO | 80 |
| | Au | 25 | | |
| | Cmpd. 1 | 60 | | |
| HIL | — | | Cmpd. 1 | 67 |
| HTL | NPB | 20 | NPB | 30 |
| PhL | 8% Cmpd. 5 in | 50 | 8% Cmpd. 5 in | 40 |
| | 9:1 Cmpd. 8:NPB | | 9:1 Cmpd. 8:NPB | |
| ETL | Cmpd. 13 | 30 | Cmpd. 13 | 30 |
| EIL | CsF | 1 | CsF | 1 |
| cathode | Al | 100 | Al | 100 |

HIL = hole injection layer;
HTL = hole transport layer;
PhL = photoactive layer;
ETL = electron transport layer;
EIL = electron injection layer (as deposited).

The OLED samples were characterized as described above for Example 1, The results are shown in Table 8.

TABLE 8
Device Results

| | Efficiency | | Voltage |
|---|---|---|---|
| Device | (cd/A) | CIE (x, y) | (V) |
| Example 4 | 29 | 0.664, 0.336 | 4.8 |
| Comp. Ex. B | 21 | 0.655, 0.345 | 4.8 |

All measurements at 1000 nits.
“CIExy” refers to the x and y color coordinates, according to the C.I.E. chromaticity scale (Commission Internationale de L'Eclairage, 1931).

It can be seen from Table 8, that the device with the new composite anode has higher efficiency. The color coordinates in the device with the new composite anode are closer to the NTSC red standard of (0.670, 0.330).

### Example 5 and Comparative Example B

This example illustrates the performance of a device with red emission color and having the new composite anode.

The photoactive layer had 8% by weight Compound 5 as the red-emissive dopant. The host was a combination of Compound 8 and NPB in a 9:1 weight ratio.

In Example 5, the anode had the configuration shown in FIG. 8. Layer 202 was M2, a 1.5 nm layer of Cr; layer 201 was M1, a 20 nm layer of Ag; and layer 204 was M4, a 60 nm layer of HAT-CN.

In Comparative Example B, the anode was an 80 nm layer of ITO. The anode was overcoated with a hole injection layer of 67 nm of Compound 1.

The devices were prepared on a glass substrate. Compound 1 was deposited by spin coating from an aqueous dispersion. All other layers were applied by evaporative deposition. The device layers are summarized in Table 9.

TABLE 9
Device Composition

| | Example 5 | | Comparative Example B | |
|---|---|---|---|---|
| Device | | Thickness | | Thickness |
| Layer | Material | (nm) | Material | (nm) |
| anode | Cr | 1.5 | ITO | 80 |
| | Ag | 20 | | |
| | HAT-CN | 10 | | |
| HIL | — | | Cmpd. 1 | 67 |
| HTL | NPB | 50 | NPB | 30 |
| PhL | 8% Cmpd. 5 in | 50 | 8% Cmpd. 5 in | 40 |
| | 9:1 Cmpd. 8:NPB | | 9:1 Cmpd. 8:NPB | |
| ETL | Cmpd. 13 | 30 | Cmpd. 13 | 30 |
| EIL | CsF | 1 | CsF | 1 |
| cathode | Al | 100 | Al | 100 |

HIL = hole injection layer;
HTL = hole transport layer;
PhL = photoactive layer;
ETL = electron transport layer;
EIL = electron injection layer (as deposited).

The OLED samples were characterized as described above for Example 1. The results are shown in Table 10.

TABLE 10
Device Results

| | Efficiency | | Voltage |
|---|---|---|---|
| Device | (cd/A) | CIE (x, y) | (V) |
| Example 5 | 36.7 | 0.65, 0.35 | 4.6 |
| Comp. Ex. B | 21 | 0.655, 0.345 | 4.8 |

All measurements at 1000 nits.
“CIExy” refers to the x and y color coordinates, according to the C.I.E. chromaticity scale (Commission Internationale de L'Eclairage, 1931).

It can be seen from Table 10, that the device with the new composite anode has higher efficiency and lower voltage.

### Examples 6 and 7 and Comparative Example C

These examples illustrate the performance of devices with red emission color and having the new composite anode.

The photoactive layer had 12% by weight Compound 11 as the red-emissive dopant. The host was 36% by weight Compound 9, 50% Compound 7. The layer additionally contained 2% by weight of Compound 4 as a hole trap.

In Example 6, the anode had the configuration shown in FIG. 13. Layer 203 was M3, a 50 nm layer of ITO; layer 201 was M1, a 18 nm layer of Ag; layer 202 was M2, a 1 nm layer of Cr; and layer 204 was M4, a 54 nm layer of Compound 1.

In Example 7, the anode had the configuration shown in FIG. 12. Layer 203 was M3, a 50 nm layer of ITO: layer 202 was M2, a 1 nm layer of Cr; layer 201 was M1, a 18 nm layer of Ag, and layer 204 was M4, a 54 nm layer of Compound 1.

In Comparative Example C, the anode was a 50 nm layer of ITO. The anode was overcoated with a hole injection layer of 54 nm of Compound 1.

The devices were prepared on a glass substrate. Compound 1 was deposited by spin coating from an aqueous dispersion. Compound 3 was deposited by spin coating from a toluene solution. The photoactive layer was deposited by spin coating from a methyl benzoate solution. All other layers were applied by evaporative deposition. The device layers are summarized in Table 11.

TABLE 11
Device Composition

| | Example 6 | | Example 7 | | Comparative Ex. C | |
|---|---|---|---|---|---|---|
| | | Thick- | | Thick- | | Thick- |
| Device | | ness | | ness | | ness |
| Layer | Material | (nm) | Material | (nm) | Material | (nm) |
| anode | ITO | 50 | ITO | 50 | ITO | 50 |
| | Ag | 18 | Cr | 1 | | |
| | Cr | 1 | Ag | 18 | | |
| | Cmpd. 1 | 54 | Cmpd. 1 | 54 | | |
| HIL | — | | — | | Cmpd. 1 | 54 |
| HTL | Cmpd. 3 | 20 | Cmpd. 3 | 20 | Cmpd. 3 | 20 |
| PhL | (a) | 70 | (a) | 70 | (a) | 78 |
| ETL | Cmpd. 14 | 10 | Cmpd. 14 | 10 | Cmpd. 14 | 10 |
| EIL | CsF | 0.7 | CsF | 0.7 | CsF | 07 |
| cathode | Al | 100 | Al | 100 | Al | 100 |

(a) Compound 9:Compound 7:Compound 4:Compound 11 in 36:50:2:12 weight ratio
HIL = hole injection layer; HTL = hole transport layer; PhL = photoactive layer; ETL = electron transport layer; EIL = electron injection layer (as deposited).

The OLED samples were characterized as described above for Example 1, The results are shown in Table 12.

TABLE 12
Device Results

| | Efficiency | | Voltage |
|---|---|---|---|
| Device | (cd/A) | CIE (x, y) | (V) |
| Example 6 | 30.4 | 0.669, 0.328 | 3.6 |
| Example 7 | 31.7 | 0.660, 0.337 | 3.65 |
| Comp. Ex. C | 19.8 | 0.646, 0.351 | 3.9 |

All measurements at 1000 nits.
“CIExy” refers to the x and y color coordinates, according to the C.I.E. chromaticity scale (Commission Internationale de L'Eclairage, 1931).

It can be seen from Table 12, that the devices with the new composite anode have higher efficiency and lower voltage. The color coordinates in the devices with the new composite anode are closer to the NTSC red standard of (0.670, 0.330).

### Example 8 and Comparative Example D

This example illustrates the performance of a device with blue emission color and having the new composite anode.

The photoactive layer had 14% by weight Compound 6 as the blue-emissive dopant. The host was Compound 10.

In Example 5, the anode had the configuration shown in FIG. 13. Layer 203 was M3, a 50 nm layer of ITO; layer 201 was M1, a 18 nm layer of Ag; layer 202 was M2, a 1 nm layer of Cr; and layer 204 was M4, a 30 nm layer of Compound 1.

In Comparative Example D, the anode was a 50 nm layer of ITO. The anode was overcoated with a hole injection layer of 20 nm of Compound 1.

The devices were prepared on a glass substrate. Compound 1 was deposited by spin coating from an aqueous dispersion. Compound 3 was deposited by spin coating from a toluene solution. The photoactive layer was deposited by spin coating from a methyl benzoate solution. All other layers were applied by evaporative deposition. The device layers are summarized in Table 13.

TABLE 13
Device Composition

| | Example 8 | | Comparative Example D | |
|---|---|---|---|---|
| Device | | Thickness | | Thickness |
| Layer | Material | (nm) | Material | (nm) |
| anode | ITO | 50 | ITO | 50 |
| | Ag | 18 | | |
| | Cr | 1 | | |
| | Cmpd. 1 | 30 | | |
| HIL | — | | Cmpd. 1 | 50 |
| HTL | Cmpd. 3 | 20 | Cmpd. 3 | 20 |
| PhL | 14% Cmpd. in | 40 | 14% Cmpd. in | 40 |
| | Cmpd. 10 | | Cmpd. 10 | |
| ETL | Cmpd. 14 | 30 | Cmpd. 14 | 30 |
| EIL | CsF | 0.7 | CsF | 0.7 |
| cathode | Al | 100 | Al | 100 |

HIL = hole injection layer;
HTL = hole transport layer;
PhL = photoactive layer;
ETL = electron transport layer;
EIL = electron injection layer (as deposited).

The OLED samples were characterized as described above for Example 1. The results are shown in Table 14.

TABLE 14
Device Results

| | Efficiency | | Voltage |
|---|---|---|---|
| Device | (cd/A) | CIE (x, y) | (V) |
| Example 8 | 4.7 | 0.144, 0.063 | 3.8 |
| Comp. Ex. D | 4.9 | 0.142, 0.204 | 3.7 |

All measurements at 1000 nits.
“CIExy” refers to the x and y color coordinates, according to the C.I.E. chromaticity scale (Commission Internationale de L'Eclairage, 1931).

It can be seen from Table 8, that the device with the new composite anode has color coordinates closer to the NTSC blue standard of (0.140, 0.080).

### Examples 9 and 10 and Comparative Example E

These examples illustrate the performance of devices with red emission color and having the new composite anode.

The photoactive layer had 8% by weight Compound 11 as the red-emissive dopant. The host was 36% by weight Compound 9, 50% Compound 7. The layer additionally contained 6% by weight of Compound 4 as a hole trap.

In Example 9, the anode had the configuration shown in FIG. 13. Layer 203 was M3, a 50 nm layer of ITO; layer 201 was M1, a 18 nm layer of Ag; layer 202 was M2, a 1 nm layer of Ni; and layer 204 was M4, a 54 nm layer of Compound 1.

In Example 10, the anode had the configuration shown in FIG. 9. Layer 203 was M3, a 50 nm layer of ITO; layer 210 was A1, an 18 nm layer of an alloy of Ag/Al (94:6 weight %); and layer 204 was M4, a 54 nm layer of Compound 1.

In Comparative Example E, the anode was a 50 nm layer of ITO. The anode was overcoated with a hole injection layer of 54 nm of Compound 1.

The devices were prepared on a glass substrate. Compound 1 was deposited by spin coating from an aqueous dispersion. Compound 3 was deposited by spin coating from a toluene solution. The photoactive layer was deposited by spin coating from a methyl benzoate solution. All other layers were applied by evaporative deposition. The device layers are summarized in Table 15.

TABLE 15
Device Composition

| | Example 9 | | Example 10 | | Comparative Ex. E | |
|---|---|---|---|---|---|---|
| | | Thick- | | Thick- | | Thick- |
| Device | | ness | | ness | | ness |
| Layer | Material | (nm) | Material | (nm) | Material | (nm) |
| anode | ITO | 50 | ITO | 50 | ITO | 50 |
| | Ag | 18 | Ag:Al | 18 | | |
| | | | (94:6) | | | |
| | Ni | 1 | Cmpd. 1 | 54 | | |
| | Cmpd. 1 | 54 | | | | |
| HIL | — | | — | | Cmpd. 1 | 54 |
| HTL | Cmpd. 3 | 20 | Cmpd. 3 | 20 | Cmpd. 3 | 20 |
| PhL | (a) | 78 | (a) | 78 | (a) | 78 |
| ETL | Cmpd. 14 | 10 | Cmpd. 14 | 10 | Cmpd. 14 | 10 |
| EIL | CsF | 0.7 | CsF | 0.7 | CsF | 0.7 |
| cathode | Al | 100 | Al | 100 | Al | 100 |

(a) Compound 9:Compound 7:Compound 4:Compound 11 in 36:50:6:8 weight ratio
HIL = hole injection layer; HTL = hole transport layer; PhL = photoactive layer; ETL = electron transport layer; EIL = electron injection layer (as deposited).

The OLED samples were characterized as described above for Example 1. The results are shown in Table 16.

TABLE 16
Device Results

| | Efficiency | | Voltage |
|---|---|---|---|
| Device | (cd/A) | CIE (x, y) | (V) |
| Example 9 | 27.8 | 0.665, 0.332 | 3.6 |
| Example 10 | 27.5 | 0.672, 0.326 | 3.8 |
| Comp. Ex. E | 19.4 | 0.648, 0.351 | 4.1 |

All measurements at 1000 nits.
“CIExy” refers to the x and y color coordinates, according to the C.I.E. chromaticity scale (Commission Internationale de L'Eclairage, 1931).

It can be seen from Table 16, that the devices with the new composite anode have higher efficiency and lower voltage. The color coordinates in the devices with the new composite anode are closer to the NTSC red standard of (0.670, 0.330).

### Examples 11 and 12 and Comparative Example F

These examples illustrate the performance of devices with green emission color and having the new composite anode.

The photoactive layer had 16% by weight Compound 15 as the green-emissive dopant. The host was 35% by weight Compound 2, 49% Compound 7.

In Example 11, the anode had the configuration shown in FIG. 13. Layer 203 was M3, a 50 nm layer of ITO; layer 201 was M1, a 18 nm layer of Ag; layer 202 was M2, a 1 nm layer of Ni; and layer 204 was M4, a 25.5 nm layer of Compound 1.

In Example 12, the anode had the configuration shown in FIG. 9. Layer 203 was M3, a 50 nm layer of ITO: layer 210 was A1, an 18 nm layer of an alloy of Ag/Al (94:6 weight %); and layer 204 was M4, a 25.5 nm layer of Compound 1.

In Comparative Example F, the anode was a 50 nm layer of ITO. The anode was overcoated with a hole injection layer of 50 nm of Compound 1.

The devices were prepared on a glass substrate. Compound 1 was deposited by spin coating from an aqueous dispersion. Compound 3 was deposited by spin coating from a toluene solution. The photoactive layer was deposited by spin coating from a methyl benzoate solution. All other layers were applied by evaporative deposition. The device layers are summarized in Table 17.

TABLE 17
Device Composition

| | Example 9 | | Example 10 | | Comparative Ex. E | |
|---|---|---|---|---|---|---|
| | | Thick- | | Thick- | | Thick- |
| Device | | ness | | ness | | ness |
| Layer | Material | (nm) | Material | (nm) | Material | (nm) |
| anode | ITO | 50 | ITO | 50 | ITO | 50 |
| | Ag | 18 | Ag:Al | 18 | | |
| | | | (94:6) | | | |
| | Ni | 1 | Cmpd. 1 | 25.5 | | |
| | Cmpd. 1 | 25.5 | | | | |
| HIL | — | | — | | Cmpd. 1 | 50 |
| HTL | Cmpd. 3 | 20 | Cmpd. 3 | 20 | Cmpd. 3 | 20 |
| PhL | (a) | 60 | (a) | 60 | (a) | 60 |
| ETL | Cmpd. 13 | 10 | Cmpd. 13 | 10 | Cmpd. 13 | 10 |
| EIL | CsF | 0.7 | CsF | 0.7 | CsF | 0.7 |
| cathode | Al | 100 | Al | 100 | Al | 100 |

(a) Compound 9:Compound 7:Compound 15 in 35:49:16 weight ratio
HIL = hole injection layer; HTL = hole transport layer; PhL = photoactive layer; ETL = electron transport layer; EIL = electron injection layer (as deposited).

The OLED samples were characterized as described above for Example 1. The results are shown in Table 18.

TABLE 18
Device Results

| | Efficiency | | Voltage |
|---|---|---|---|
| Device | (cd/A) | CIE (x, y) | (V) |
| Example11 | 120.6 | 0.326, 0.648 | 3.6 |
| Example 12 | 130.0 | 0.319, 0.655 | 3.8 |
| Comp. Ex. F | 82.4 | 0.352, 0.622 | 3.5 |

All measurements at 1000 nits.
“CIExy” refers to the x and y color coordinates, according to the C.I.E. chromaticity scale (Commission Internationale de L'Eclairage, 1931).

It can be seen from Table 18, that the devices with the new composite anode have higher efficiency. The color coordinates in the devices with the new composite anode are closer to the NTSC green standard of (0.210, 0.710).

Note that not all of the activities described above in the general description or the examples are required, that a portion of a specific activity may not be required, and that one or more further activities may be performed in addition to those described. Still further, the order in which activities are listed are not necessarily the order in which they are performed.

In the foregoing specification, the concepts have been described with reference to specific embodiments. However, one of ordinary skill in the art appreciates that various modifications and changes can be made without departing from the scope of the invention as set forth in the claims below. Accordingly, the specification and figures are to be regarded in an illustrative rather than a restrictive sense, and all such modifications are intended to be included within the scope of invention.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

It is to be appreciated that certain features are, for clarity, described herein in the context of separate embodiments, may also be provided in combination in a single embodiment. Conversely, various features that are, for brevity, described in the context of a single embodiment, may also be provided separately or in any subcombination. Further, reference to values stated in ranges include each and every value within that range.

What is claimed is:

1. A composite electrode comprising one of (a) a single layer A1 and (b) a bilayer, wherein the single layer A1 comprises an alloy of a first metal having an electrical conductivity greater than 10⁵ Scm⁻¹ and a real refractive index less than 2.1 in the range of 380 to 780 nm; and the bilayer comprises:
(a) layer M1 having a first thickness and comprising the first metal; and
(b) layer M2 having a second thickness and consisting of a second metal or an alloy of the second metal, where the second metal has an electrical conductivity less than 10⁵ Scm⁻¹;
wherein layer M1 is in physical contact with layer M2 and the first thickness is greater than the second thickness.

2. The composite electrode of claim 1, wherein the first metal is copper, silver, or gold.

3. The composite electrode of claim 1, wherein A1 comprises silver/gold, silver/gold/copper, gold/nickel, gold/palladium, silver/germanium, silver/copper, silver/palladium, silver/nickel, or silver/titanium.

4. The composite electrode of claim 1, wherein layer M1 has a thickness of 5-50 nm and layer M2 has a thickness of 0.1-5 nm.

5. The composite electrode of claim 1, wherein the metal of layer M2 comprises chromium, nickel, palladium, titanium or germanium.

6. The composite electrode of claim 1, further comprising a second layer M2 having a thickness which is less than the first thickness.

7. The composite electrode of claim 1, further comprising a layer M3 comprising indium-tin-oxide, indium-zinc-oxide, aluminum-tin-oxide, aluminum-zinc-oxide, or zirconium-tin-oxide.

8. The composite electrode of claim 1, further comprising a layer M4 comprising an organic hole injection material.

9. The composite electrode of claim 8, wherein the hole injection material comprises hexaazatriphenylene hexacarbonitrile or a conducting polymer doped with a colloid-forming polymeric sulfonic acid.

10. An organic electronic device comprising in order, a substrate, an anode, a photoactive layer, and a cathode, wherein the anode is a composite electrode comprising one of (a) a single layer A1 and (b) a bilayer, wherein the single layer A1 comprises an alloy of a first metal having an electrical conductivity greater than 10⁵ Scm⁻¹ and a real refractive index less than 2.1 in the range of 380 to 780 nm; and the bilayer comprises;
(a) layer M1 having a first thickness and comprising the first metal; and
(b) layer M2 having a second thickness and consisting of a second metal or an alloy of the second metal, where the second metal has an electrical conductivity less than 10⁵ Scm⁻¹;
wherein layer M1 is in physical contact with layer M2 and the first thickness is greater than the second thickness.

11. The device of claim 10, wherein the first metal is copper, silver, or gold.

12. The device of claim 10, wherein layer A1 comprises silver/gold, silver/gold/copper, gold/nickel, gold/palladium, silver/germanium, silver/copper, silver/palladium, silver/nickel, or silver/titanium.

13. The device of claim 10, wherein layer M1 has a thickness of 5-50 nm and layer M2 has a thickness of 0.1-5 nm.

14. The device of claim 10, wherein the metal of layer M2 comprises chromium, nickel, palladium, titanium or germanium.

15. The device of claim 10, wherein the anode further comprises a second layer M2 having a thickness less than the first thickness.

16. The device of claim 10, wherein the anode further comprises layer M3 comprising indium-tin-oxide, indium-zinc-oxide, aluminum-tin-oxide, aluminum-zinc-oxide, or zirconium-tin-oxide, wherein layer M3 is adjacent the substrate.

17. The device of claim 10, wherein the anode further comprises layer M4 comprising an organic hole injection material, wherein layer M4 is adjacent the photoactive layer.

18. The device of claim 17, wherein the hole injection material comprises hexaazatriphenylene hexacarbonitrile or a conducting polymer doped with a colloid-forming polymeric sulfonic acid.
